(19) United States
(12) Patent Application Publication
(10) Pub. No.: US 2024/0039231 A1
(43) Pub. Date: Feb. 1, 2024

(54) SLAB LASER WITH FOLDED PUMP FOR EXTENDED PERFORMANCE

(71) Applicant: OneLight Sensing, LLC, San Jose, CA (US)

(72) Inventor: Michael G. Solonenko, San Diego, CA (US)

(21) Appl. No.: 18/226,963

(22) Filed: Jul. 27, 2023

Related U.S. Application Data
(60) Provisional application No. 63/393,171, filed on Jul. 28, 2022.

(51) Int. Cl. H01S 3/08; H01S 3/094; H01S 3/06; H01S 3/0941

(52) U.S. Cl. CPC H01S 3/08095; H01S 3/09403; H01S 3/0606; H01S 3/0941

(57) ABSTRACT

A device may include an active material, a primary optical system, and a pump optical system. The primary optical system forms a primary folded optical path through the active material for a primary optical beam. The pump optical system forms a pump folded optical path through the active material for pump light. The pump folded optical path overlaps with the primary folded optical path in the active material. The pump light propagating along the pump folded optical path pumps the active material to amplify the primary optical beam propagating through the active material along the primary folded optical path.

### CROSS-REFERENCE TO RELATED APPLICATION

This application claims priority to U.S. Provisional Patent Application Ser. No. 63/393,171, “Slab Laser with Folded Pump for Extended Performance,” filed on Jul. 28, 2022, the subject matter of which is incorporated herein by reference in its entirety.

### BACKGROUND

### 1. Technical Field

This disclosure relates generally to optical amplifiers, and more particularly, to optical amplifiers with a folded pump optical path through an active material and a folded optical path through the active material for a primary optical beam.

### 2. Description of Related Art

Laser pumping is the act of energy transfer from an external source into an active material (also “gain medium” or “active medium”) to a laser. The pump energy is usually provided in the form of light or electric current, but more exotic sources have been used, such as chemical or nuclear reactions. The energy is absorbed by the active material, thus producing excited states in the atoms of the active material. When the number of particles in one excited state exceeds the number of particles in the ground state or a less-excited state, population inversion is achieved. In this condition, stimulated emission occurs, and the active material can act as an optical amplifier or optical oscillator.

### SUMMARY

A device may include an active material, a primary optical system, and a pump optical system. The primary optical system forms a primary folded optical path through the active material for a primary optical beam. The pump optical system forms a pump folded optical path through the active material for pump light. The pump folded optical path overlaps with the primary folded optical path in the active material. The pump light propagating along the pump folded optical path pumps the active material to amplify the primary optical beam propagating through the active material along the primary folded optical path.

Other aspects include components, devices, systems, improvements, methods, processes, applications, computer readable mediums, and other technologies related to any of the above.

### BRIEF DESCRIPTION OF THE DRAWINGS

Embodiments of the disclosure have other advantages and features which will be more readily apparent from the following detailed description and the appended claims, when taken in conjunction with the examples in the accompanying drawings, in which:

FIG. 1 is a diagram of a first example laser system configured to perform laser pumping.

FIGS. 2A and 2B are diagrams of a second example laser system configured to perform laser pumping.

FIGS. 3A and 3B are diagrams of a third example laser system configured to perform laser pumping.

FIG. 4 is an example graph of pump photon depth vs diode temperature.

FIG. 5 is an example graph of linear gain vs. position along pump light path during amplification.

### DETAILED DESCRIPTION

The figures and the following description relate to preferred embodiments by way of illustration only. It should be noted that from the following discussion, alternative embodiments of the structures and methods disclosed herein will be readily recognized as viable alternatives that may be employed without departing from the principles of what is claimed.

### Laser Optical System

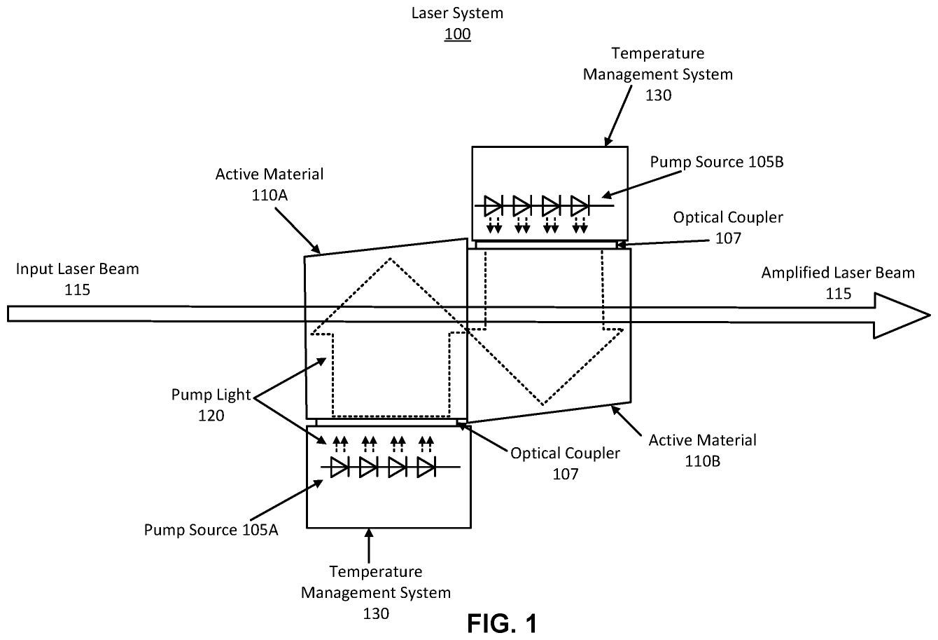

FIG. 1 is a diagram of a first example laser system 100 configured to perform laser pumping. The system 100 includes pump sources 105A and 105B (collectively 105), active materials 110A and 110B (collectively 110), and a laser beam 115 with an optical path through the active material 110. The pump sources 105 emit pump light 120 that propagates though the active material 110 and is absorbed by the active material 110, thus amplifying the laser beam 115 as the laser beam 115 propagates through the active material 110. In this example, the pump sources 105 are arrays of diode lasers. Since diode lasers are vulnerable to temperature changes (as further described below), the laser system 100 also includes a temperature management system 130 (e.g., a water chilling system) that may provide active cooling or heating to control the temperature of the pump sources 105 (e.g., 130 prevents the diode temperature from raising more than 2° C.) over a range of different operating conditions (e.g., for optimum performance). The laser system 100 also includes optical couplers 107 to couple light from the pump sources 105 into the active material 110. The optical couplers may be optically matching and anti-reflective to increase the amount of pump light 120 coupled into the active material 110.

Typically, the direction of the pump beam and the amplified laser beam are defined by the laser optical design and mechanical packaging considerations. The laser system 100 may be referred to as a “side pumped” configuration because the pump light 120 is injected from the side, approximately perpendicular to the optical path of the laser beam 115 (e.g., the intersection angle is approximately 90 to 70 degrees from the direction of the laser beam 115. Said differently, the pump light 120 direction is zero to twenty degrees from a direction perpendicular to the propagation direction of the laser beam 115)

In the example laser system 100 of FIG. 1, the pump light 120 from each pump source 105A, 105B propagates only once through the active material 110 (in other words, the optical path of the pump light 120 only passes through the active material 110 once) because, due to the temperature management system 130 (e.g., optimizing the pump wavelength for peak absorption), the pump light 120 is fully absorbed after only one pass.

Laser Optical System with Folded Laser Optical Path

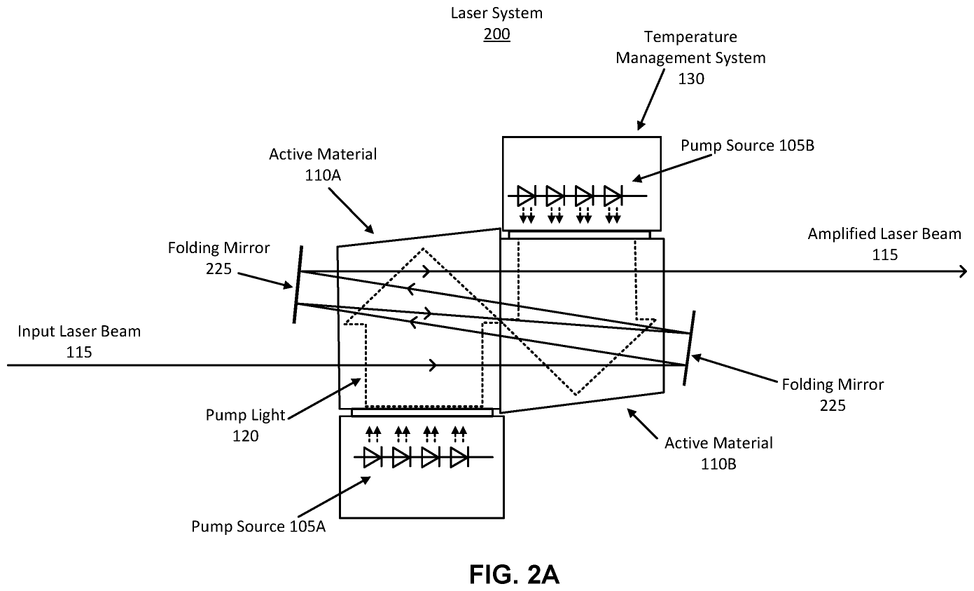

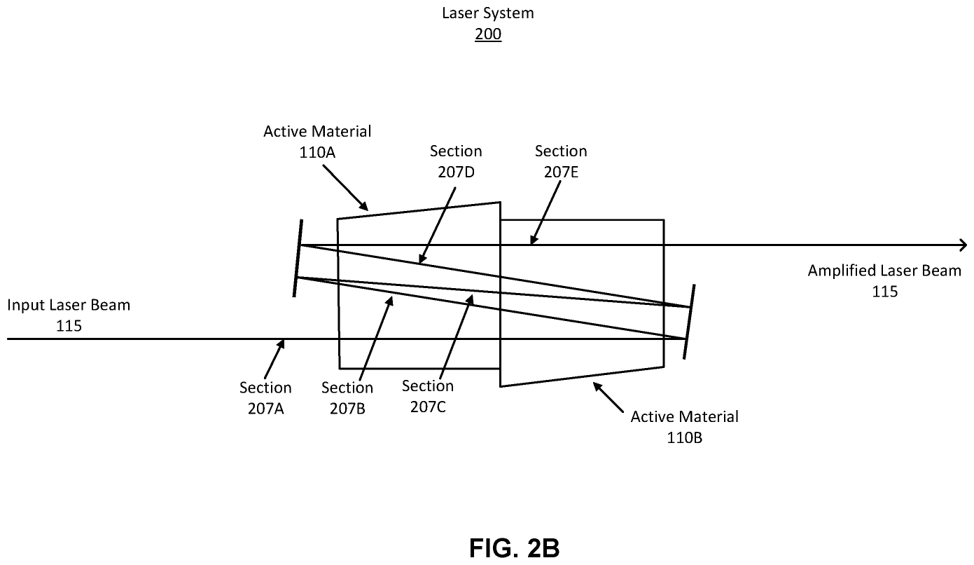

FIGS. 2A and 2B are diagrams of a second example side pumped laser system 200 configured to perform laser pumping. Hereafter “FIG. 2” refers to FIGS. 2A and 2B collectively. FIG. 2B is similar to FIG. 2A, except various components are so the laser folded optical path can be clearly seen. The laser system 200 is similar to the laser system 100 of FIG. 1 in that it includes pump sources 105 configured to emit pump light 120 that propagates though active materials 110A and 110B, thus amplifying a laser beam 115 as the beam 115 propagates through the active material 110 (note that the laser beam 115 is illustrated as a line in FIG. 2 for simplicity). However, the laser system 200 is improved relative to laser system 100 because the laser beam 115 passes through the active material 110 multiple times. Multiple passes through the active material 110 may result in additional amplification relative to the laser system 100. Additionally, the folded laser optical path may result in a more compact and lighter system than a system with a single, unfolded laser optical path through the active material 110 (e.g., system 100). A folded laser optical path allows a simpler and more efficient implementation of heat evacuation from the active material 110 and thus improves overall performance when the system operates close to its thermal limit.

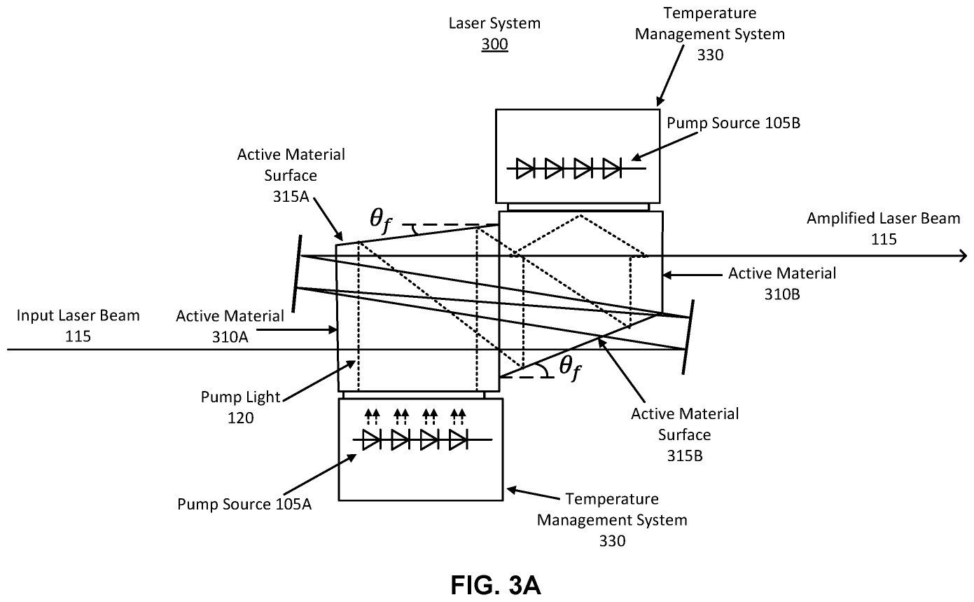

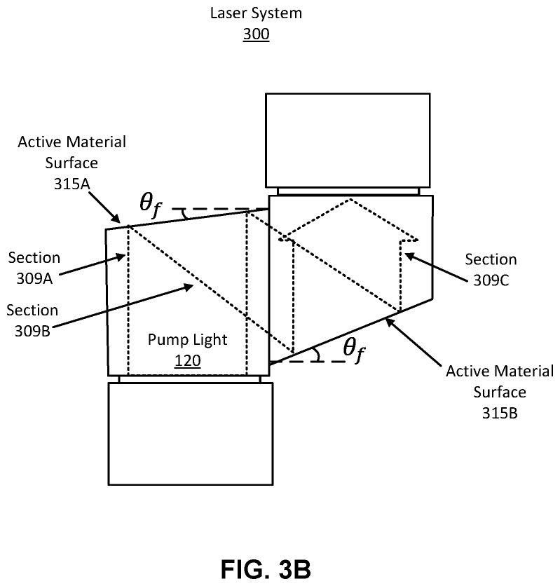

In the example of FIG. 2, the laser optical path includes five sections 207A-207E that each pass through the active material 110 (more specifically, each of the five sections 207 pass through both 110A and 110B). More generally, the laser optical path includes a fixed number of distinct sections that pass through the active material 110. As described herein, a section of an optical path spans from an optical component (that folds the optical path) to another optical component (that also folds the optical path) (note that the second optical components of sections 207A and 207E are not illustrated in FIG. 2). Distinct sections refers to optical path sections that are distinguishable from each other. Thus, optical pumping via a fixed number of distinct sections as described above contrasts with optical pumping via an optical resonator, which includes an indefinite number of sections. Furthermore, a section of an optical path that “passes through” or “propagates through” active material refers to a section that includes active material for a least part of the segment (this includes a segment entirely in active material (see e.g., sections 309A-309C described with respect to FIG. 3)). Sections 207A, 207C and 207E may be referred to as “forward” sections because light propagates from left to right in the figure. Sections 207B and 207D may be referred to as “reverse” sections because light propagates from the right to the left in the figure.

The folded laser optical path through the active material 110 is formed by a laser optical system with optical components that direct the laser beam 115. In the example of FIG. 2, the optical system includes two folding mirrors 225 that form the zigzag pattern illustrated in FIG. 2. More generally, to form a folded laser optical path, each of the optical components of the laser optical system may direct, widen, slim, reflect, diffract, refract, disperse, amplify, reduce, combine, separate, or polarize (or some combination thereof) the laser beam 115 as it propagates. Example optical components of the folded laser optical path include metalized features, optical gratings, mirrors, prismatic structures, Fresnel structures, corner reflectors, retroreflectors, or some combination thereof. Furthermore, optical components that form the folded laser optical path are described herein in terms of ‘directing’ or ‘redirecting’ the laser beam 115, however this is for purposes of simplicity of description to include any one or more of the light property changes described above as well as any other manipulation of the laser beam 115 not specifically called out above.

When a pump source (e.g., 105) pumps an active material (e.g., 110) of a laser (e.g., 115) to produce a higher-energy state, pump efficiency depends, among other factors, on how well the pump light wavelength (or wavelengths) matches an absorption wavelength band of the active material. Efficient pumping leads to a large population inversion in the active material, which is one of the conditions for light stimulated emission. However, the output wavelength of a diode laser may be highly temperature dependent. For example, though a specific diode laser may be well-suited to pumping a particular active material, if the temperature changes, the output wavelength of the pump light from the diode laser may shift, thus resulting in inefficient or ineffective pumping (e.g., if the wavelength shifts beyond the active material absorption band(s). Thus, the total absorption of the pump light by the active material drops, resulting in reduction of the laser output power (or laser pulse energy).

Diode lasers of a laser system (e.g., 100 or 200) may change temperature, and thus shift their output wavelength, for any number of reasons. For example, a laser system may operate over a wide temperature range or operate at high duty cycles (e.g., over 10 percent). To reduce undesired temperature changes (e.g., changes larger than 2° C.), laser systems may use expensive, bulky, or complex temperature management systems.

Laser Optical System with Folded Pump Optical Path

A pump optical path of a laser system may be folded to extend the interaction (propagation) range over which the pump light 150 can be absorbed by the active material 110. With a folded pump optical path that crosses and re-crosses the active material 110, the pump light 120 may be (e.g., completely) absorbed over the optical path in the active material 110 over extended temperature variations (e.g., changes over 2 or 5° C.) despite lower absorption per path-length. This may reduce or eliminate the need for (e.g., expensive, bulky, and complex) temperature management systems, for example, during high pulse power, high duty cycle, or high ambient temperature operation.

FIGS. 3A and 3B are diagrams of a third example side pumped laser system 300 configured to perform laser pumping. Hereafter “FIG. 3” refers to FIGS. 3A and 3B collectively. FIG. 3B is similar to FIG. 3A, except various components are omitted so the pump folded optical path can be clearly seen. The laser system 300 is similar to the laser system 200 of FIG. 2 in that it includes pump sources 105 configured to emit pump light 120 that propagates though active materials 310A and 310B (collectively 310), thus amplifying a laser beam 115 as the beam 115 propagates through the active material 310 along the laser optical path. However, the laser system 300 of FIG. 3 is improved relative to laser system 200 because it includes a folded pump optical path that overlaps with the laser optical path in the active material 310. More specifically, the folded optical path of the pump light 120 includes a fixed number of distinct sections 309A-309CE that intersect sections of the laser optical path. Thus, the laser system 300 includes a folded optical path for the laser beam 115 and a folded optical path for the pump light 120.

In the folded pump optical path improvement of FIG. 3, pump light 120 from pump source 105A that is not absorbed by active material 310A (e.g., due the laser diodes' temperature increasing) is redirected back through the active material 310 to propagate into the adjacent slab of active material 310B. More specifically, unabsorbed pump light propagating along section 309A of the pump optical path is directed along section 309B, and any remaining unabsorbed pump light along 309B is then directed along section 309C. Similarly, unabsorbed pump light from source 105B propagating through active material 310B (downward along section 309C) is directed to propagate through active material 310A (diagonal along section 309B and then downward along section 309A). For simplicity, pump light from source 105B is not illustrated in FIG. 3. This redirection increases the path length of the pump light 120 through the active material 310, thus increasing absorption of the pump light 120, even in sub-optimal operating conditions (e.g., high temperatures). Said differently, the folded pump optical path extends the interaction range of the pump light 120 and may enable the laser system 300 to operate effectively at larger temperature ranges without complex cooling schemes. Additionally, the folded pump optical path still enables the laser system 300 to operate at normal conditions (e.g., resulting in the laser diodes emitting optimal wavelengths). In these operating conditions, the pump light is still absorbed and thus still amplifies the laser beam 115, albeit at different parts of the active material 310 due to the pump light being absorbed sooner along the pump optical path.

The folded pump optical path is formed by a pump optical system with optical components that direct the pump light 120. To form the folded pump optical path, each of the optical components of the pump optical system may direct, widen, slim, reflect, diffract, refract, disperse, amplify, reduce, combine, separate, or polarize (or some combination thereof) the pump light 120 as it propagates. Example optical components of the folded pump optical path include metalized features, optical gratings, mirrors, prismatic structures, Fresnel structures, corner reflectors, retroreflectors, or some combination thereof. Furthermore, optical components that form the folded pump optical path are described in terms of ‘directing’ or ‘redirecting’ the pump light, however this is for purposes of simplicity of description to include any one or more of the pump light property changes described above as well as any other manipulation of pump light beams not specifically called out above.

In the example of FIG. 3, the pump optical system includes surfaces 315A, 315B (collectively 315) of the active material 310. Specifically, the surfaces 315 are angled to reflect unabsorbed pump light 120 (e.g., via total internal refection) back through the active material 310. Reflection may occur by dielectric internal reflection. In some embodiments, surfaces 315 include a reflective coating (e.g., a mirror similar to 225). The folding angle θ_{f} of each surface may be configured (e.g., optimized) to increase path length or likelihood of absorption and, thus, likelihood of contributing to active material 310 state population inversion. In some embodiments, the pump optical system is designed to balance path length, population inversion in overlapping path segments, and angular distribution of the pump light, possibly among other factors. Note that the folding angle θ_{f} may be different for each surface 315A and 315B (e.g., depending on the shape and size of the active material 310).

The adjacent slabs of active material 310A and 310B may be joined with zero gap or an index-matching gap filler to reduce (e.g., minimize) reflection of pump light 120 at the slab-slab interface. Alternatively, the laser system 300 may be implemented as a single slab of active material in particular shape (e.g., with angled surfaces 315A, 315B). Furthermore, other geometries active material are possible. For example, the active material may be shaped to be a concave or convex mirror, or shaped as to direct the pump preferentially to some particular underutilized areas of the crystal.

As stated above, the improved laser system 300 does not require an expensive, bulky, or complex temperature management system since the longer path length enables the pump light 120 to be absorbed even if the pump sources 105 emit suboptimal wavelengths. That being said, in some embodiments, the laser system 300 includes a (e.g., cheaper, smaller, or less complex) temperature management system 330 to avoid larger temperature fluctuations (e.g., 330 is used to prevent temperature fluctuations more than 25° C.) that may significantly impact operation of the laser system 300 (e.g., fluctuations larger than 25° C. result in little or no pump light absorption).

### Example Graphs

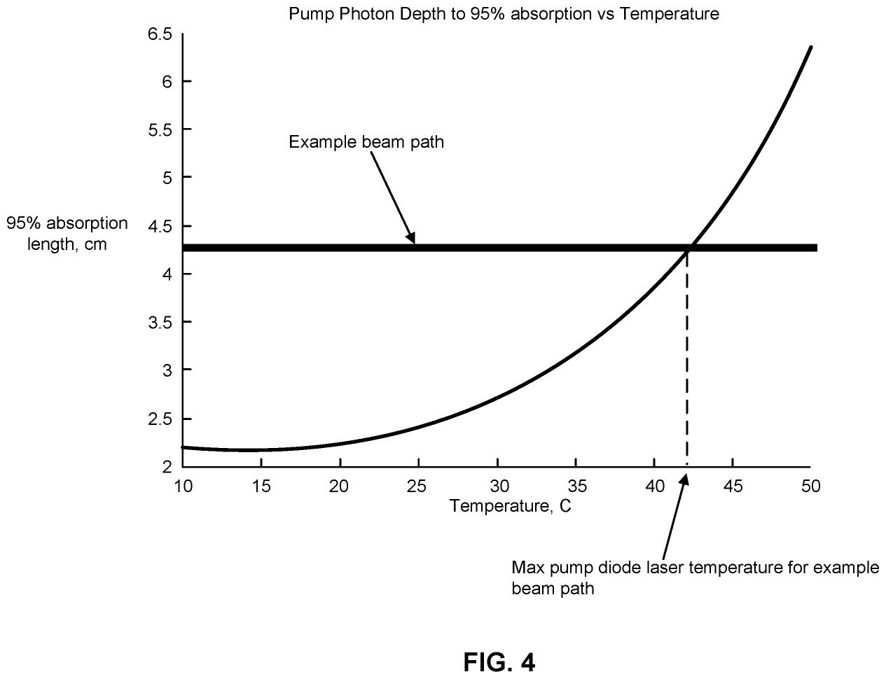

FIG. 4 is an example graph of pump photon depth (for 95% absorption in an Nd:YLF active material vs. diode temperature. As previously discussed, pump light absorption in an active material may be highly dependent on the wavelength of the light, which in turn varies over pump diode temperature. An example of this dependency is illustrated in FIG. 4. At low diode temperatures (e.g., 20° C.), the path length is short because the active material absorbs pump photons efficiently and reaches high state population inversion. However, as temperature increases, the path length for pump photons increases, thus reducing absorption efficiency. More generally, the distance that pump light propagates through an active material to be absorbed increases with increasing diode temperature.

Note that, for a folded pump path implementation, diode temperature changes, may alter the distribution of active material in the metastable state and thus cause the input-to-output amplification distribution curve to shift. The input-to-output folded path may be designed to improve (e.g., optimize) overall optical gain as temperature changes. However, different sections of the active material may contribute to gain-per-millimeter differently, depending on temperature distribution.

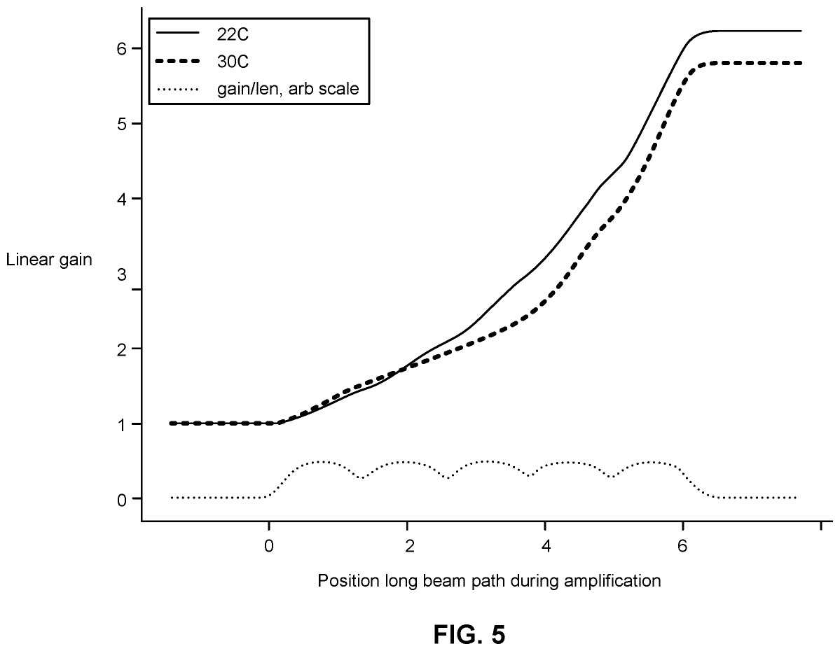

FIG. 5 is an example graph of gain and gain-per-length (the vertical axis) along the folded optical path, unfolding sections 207A, 207B, 207C, 207D and 207E into a single cumulative position along the laser path, and represented by the horizontal axis. The folded pump laser paths produce greater population inversion in the active material where they overlap most, near the mid-points of segments 207A, 207B, 207C, 207D and 207E in FIG. 2B. In addition to gain-per-length, the graph shows an example of how gain distribution through a laser amplifier's optical path may change with diode temperature. Although the pump wavelength is shifted to lower efficiency and hence lower gain-per-length in some parts of the path, the folded pump path compensates for the reduction. More specifically, the graph includes plots for different diode temperatures, specifically 22° C. and 30° C. In other words, the graph shows an example of how gain distribution through a laser amplifier's optical path may change with diode temperature. At the lower temperature (i.e., 22° C.), the pump diode wavelength is absorbed by the active material effectively. This results in a gain per length similar to the solid-line trace. The beam is amplified when it crosses those parts of the active material which are pumped by the diode light. This results in the 22° C. plot following typical amplitude growth curve. At the higher temperature (i.e., 30° C.-35° C.), the overlap between the Pump Diodes emission spectrum and active media absorption spectrum may change (become less). This generally leads to the reduction of the efficiency of the pump diode energy transfer into the amplified light. However, a folded optical path for the pump light may result in overall same absorption of the pump beam at higher temperatures as in that case the pump beam propagates within a crystal for longer length due to smaller absorption per unit length.

### Configuration Overview

In some aspects, the techniques described herein relate to a device (e.g., 300) including: an active material (e.g., 310); a primary optical system (e.g., including folding mirrors 225) that forms a primary folded optical path (e.g., including sections 207A-207E) through the active material for a primary optical beam (e.g., laser beam 115); and a pump optical system (e.g., including surfaces 315A and 315B) that forms a pump folded optical path (e.g., including sections 309A-309C) through the active material for pump light (e.g., 120), the pump folded optical path overlapping with the primary folded optical path in the active material. The pump light propagating along the pump folded optical path pumps the active material to amplify the primary optical beam propagating through the active material along the primary folded optical path.

In some aspects, the primary folded optical path includes a section that intersects the pump folded optical path multiple times, for example, two, three, four, five, or more times (e.g., referring to FIGS. 2B and 3A, sections 207C and 207D of the laser optical path each intersect the pump optical path three times). The folded optical path may include alternating forward and reverse directions, as exemplified by Sections 207A-E in FIGS. 2-3A. In some aspects, the pump folded optical path includes a section that intersects the primary folded optical path multiple times, for example, two, three, four, five, or more times (e.g., referring to FIG. 3, section 309A of the pump optical path intersects the laser optical path five times).

In some aspects, the primary folded optical path includes a section that intersects another section of the primary folded optical path. In some aspects, the primary folded optical path passes through the active material multiple times (e.g., the laser optical path passes through active material 310 five times in FIGS. 2A-3A). In some aspects, the primary folded optical path includes a fixed number of distinct sections that include the active material. In some aspects, the primary optical beam passes through the active material a fixed number of times (e.g., the laser optical path passes through active material 310 only five times in FIGS. 2A-3A).

In some aspects, the primary folded optical path includes a zigzag path (see e.g., FIGS. 2A-3A). In some aspects, the pump folded optical path includes a zigzag path (see e.g., FIG. 3).

In some aspects, a propagation direction of the primary optical beam through the active material is approximately transverse to a propagation direction of the pump light in the active material (see e.g., 3A). In some aspects, a segment of the primary folded optical path intersects with a segment of the pump folded optical path at an angle between 70 and 90 degrees.

In some aspects, the pump optical system includes one or more surfaces of the active material that direct pump light (e.g., surfaces 315). In some aspects, the active material includes first, second, and third surface portions. The first surface portion (e.g., the bottom surface of 310A which is coupled to 107 and receives pump light 120 from pump source 105A) is arranged to receive pump light (e.g., 120) from a pump source (e.g., 105A), the second surface portion (e.g., surface 315A) is opposite the first surface portion and angled to direct pump light propagating from the first surface portion and unabsorbed by the active material toward the third surface portion (e.g., surface 315B) (the third surface portion is different from the first surface portion).

In some aspects, the primary optical system includes one or more mirrors (e.g., 225) that, at least in part, form the primary folded optical path. In some aspects, the pump optical system includes one or more mirrors that, at least in part, form the pump folded optical path.

In some aspects, the primary folded optical path is a free space optical path (e.g., sections 207A-207E form a free space optical path that passes through active material 110). In some aspects, the pump folded optical path is a free space optical path (e.g., sections 309A-309C of the pump light 120 aren't propagating in a waveguide or optical fiber). In this context, a free space optical path contrasts with a “guided” path, which refers to mode propagation in a wave guide. Thus, in some aspects, neither the primary optical system nor the pump optical system includes a waveguide (e.g., an optical fiber). In some aspects, the pump optical system is different from the primary optical system (see e.g., FIG. 3A). Said differently, the pump optical system is not the same optical system as the primary optical system. In some aspects, one or more optical components of the pump optical system are not optical components of the primary optical system. Said differently, one or more optical components of the pump optical system are different components than the optical components of the primary optical system.

In some aspects, the device includes an array of laser diodes (see e.g., FIG. 3A) configured to emit the pump light.

In some aspects, the device is a side pumped laser (see e.g., FIG. 3A).

Although not illustrated in FIGS. 1-3B, in some embodiments, one or more sections of a pump optical path may be parallel with one or more sections a primary optical path.

Although the descriptions above refer to folded optical paths, the descriptions are also applicable to systems where the primary optical beam optical path or the pump optical path is are curved, rather than folded.

Although the above descriptions are in the context of laser amplification, embodiments should not be limited to this. For example, the above descriptions may be applicable for an optical pumping region of an optical gain device (e.g., a laser oscillator) or for non laser systems.

Other aspects include components, devices, systems, improvements, methods, processes, applications, computer readable mediums, and other technologies related to any of the above.

### Additional Considerations

Although the detailed description contains many specifics, these should not be construed as limiting the scope of the invention but merely as illustrating different examples. It should be appreciated that the scope of the disclosure includes other embodiments not discussed in detail above. Various other modifications, changes and variations which will be apparent to those skilled in the art may be made in the arrangement, operation and details of the method and apparatus disclosed herein without departing from the spirit and scope as defined in the appended claims. Therefore, the scope of the invention should be determined by the appended claims and their legal equivalents.

Any reference to “one embodiment” or “an embodiment” means that a particular element, feature, structure, or characteristic described in connection with the embodiment is included in at least one embodiment. The appearances of the phrase “in one embodiment” in various places in the specification are not necessarily all referring to the same embodiment. Similarly, use of “a” or “an” preceding an element or component is done merely for convenience. This description should be understood to mean that one or more of the elements or components are present unless it is obvious that it is meant otherwise.

The terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

What is claimed is:

1. A device comprising:
an active material;
a primary optical system that forms a primary folded optical path through the active material for a primary optical beam; and
a pump optical system that forms a pump folded optical path through the active material for pump light, the pump folded optical path overlapping with the primary folded optical path in the active material, wherein pump light propagating along the pump folded optical path pumps the active material to amplify the primary optical beam propagating through the active material along the primary folded optical path.

2. The device of claim 1, wherein the primary folded optical path includes a section that intersects the pump folded optical path multiple times.

3. The device of claim 1, wherein the pump folded optical path includes a section that intersects the primary folded optical path multiple times.

4. The device of claim 1, wherein the primary folded optical path includes a section that intersects another section of the primary folded optical path.

5. The device of claim 1, wherein the primary folded optical path passes through the active material multiple times.

6. The device of claim 1, wherein the primary optical beam passes through the active material a fixed number of times.

7. The device of claim 1, wherein the primary folded optical path includes a zigzag path.

8. The device of claim 1, wherein the pump folded optical path includes a zigzag path.

9. The device of claim 1, wherein a propagation direction of the primary optical beam through the active material is approximately transverse to a propagation direction of the pump light in the active material.

10. The device of claim 1, wherein a segment of the primary folded optical path intersects with a segment of the pump folded optical path at an angle between 70 and 90 degrees.

11. The device of claim 1, wherein a segment of the primary folded optical path intersects with a segment of the pump folded optical path at an angle between 10 and 70 degrees.

12. The device of claim 1, wherein the pump optical system includes one or more surfaces of the active material that direct pump light.

13. The device of claim 1, wherein the active material includes first, second, and third surface portions, the first surface portion arranged to receive pump light from a pump source, the second surface portion opposite the first surface portion and angled to direct pump light propagating from the first surface portion and un-absorbed by the active material toward the third surface portion.

14. The device of claim 1, wherein the primary optical system includes one or more mirrors that, at least in part, form the primary folded optical path.

15. The device of claim 1, wherein the pump optical system includes one or more mirrors that, at least in part, form the pump folded optical path.

16. The device of claim 1, wherein the primary folded optical path is a free space optical path.

17. The device of claim 1, wherein the pump folded optical path is a free space optical path.

18. The device of claim 1, wherein neither the primary optical system nor the pump optical system includes a waveguide.

19. The device of claim 1, wherein the pump optical system is different from the primary optical system.

20. The device of claim 1, wherein optical components of the pump optical system are not optical components of the primary optical system.
